(19) United States
(12) Patent Application Publication
(10) Pub. No.: US 2018/0019418 A1
(43) Pub. Date: Jan. 18, 2018

(54) DISPLAY DEVICE

(71) Applicant: Japan Display Inc., Minato-ku (JP)

(72) Inventors: Daisuke SONODA, Tokyo (JP); Tatsuya IDE, Tokyo (JP); Rintaro MAKINO, Tokyo (JP); Yasushi KAWATA, Tokyo (JP); Takumi SANO, Tokyo (JP)

(73) Assignee: Japan Display Inc., Minato-ku (JP)

(21) Appl. No.: 15/645,195

(22) Filed: Jul. 10, 2017

(30) Foreign Application Priority Data
Jul. 15, 2016 (JP) 2016-140364

(51) Int. Cl. H01L 51/00; H01L 27/32; H01L 51/52

(52) U.S. Cl. CPC H01L 51/0097; H01L 51/5246; H01L 27/3276; H01L 2251/5338

(57) ABSTRACT

According to one embodiment, a display device includes an insulating substrate on which a display function layer is provided, and a protection member attached onto the insulating substrate, and the insulating substrate further includes a first surface on which the display function layer is formed and a second surface on an opposite side to the first surface, on which the protection member is attached, and at least one of the first surface and the second surface includes a projection and a recess.

### CROSS-REFERENCE TO RELATED APPLICATIONS

This application is based upon and claims the benefit of priority from Japanese Patent Application No. 2016-140364, filed Jul. 15, 2016, the entire contents of which are incorporated herein by reference.

### FIELD

Embodiments described herein relate generally to a display device.

### BACKGROUND

There has been a demand of narrowing the frame in display devices comprising organic electroluminescence (EL) elements or liquid crystal display devices. Under these circumstances, display devices which employ a flexible substrate are being developed. In such display devices, the frame area is reduced by bending the flexible substrate.

The manufacture of such a display device requires a processing step of peeling a flexible substrate off from, for example a support substrate such as a glass substrate. Here, if a foreign matter or the like is attached to the support substrate and a laser beam for peeling-off is irradiated towards the support substrate, laser beam may be absorbed into the foreign matter, thereby causing a peeling error. Moreover, if the foreign matter is firmly stuck onto the support substrate, washing carried out before the irradiating of the laser beam cannot remove the foreign matter only by itself.

### BRIEF DESCRIPTION OF THE DRAWINGS

FIG. 1 is a perspective view showing a structure of a display device according to this embodiment.

FIG. 2 is a cross-section schematically showing a display area of the display device of FIG. 1.

FIG. 3 is a cross-section schematically showing another example of the display area of the display device of FIG. 1.

FIG. 4 is a partially enlarged cross-section showing a portion enclosed with a dotted line shown in FIGS. 2 and 3.

FIG. 5 is a cross-section schematically showing a method of manufacturing of the display device of FIG. 1.

FIG. 6 is a cross-section schematically showing a manufacturing step which follows that of FIG. 5.

FIG. 7 is a cross-section schematically showing a state of a glass substrate before washed.

FIG. 8 is a cross-section schematically showing a manufacturing step which follows that of FIG. 6.

FIG. 9 is a cross-section schematically showing irradiation of laser beam.

FIG. 10 is a cross-section schematically showing a manufacturing step which follows that of FIG. 8.

FIG. 11 is a cross-section schematically showing a manufacturing step which follows that of FIG. 10.

FIG. 12 is a cross-section schematically showing a manufacturing step which follows that of FIG. 11.

FIG. 13 is a cross-section schematically showing a state of a bend region of a display panel after bent.

### DETAILED DESCRIPTION

In general, according to one embodiment, a display device includes an insulating substrate on which a display function layer is provided, and a protection member attached onto the insulating substrate, and the insulating substrate further includes a first surface on which the display function layer is formed and a second surface on an opposite side to the first surface, on which the protection member is attached, and at least one of the first surface and the second surface includes a projection and a recess.

According to another embodiment, a method of manufacturing a display device includes forming an insulating substrate on a glass substrate comprising a projection and a recess, forming an array layer containing a switching element on the insulating substrate, forming a display function layer on the array layer, irradiating a laser beam onto a surface of the glass substrate, on which the insulating substrate is not formed, and peeling the insulating substrate off from the glass substrate.

Embodiments will be described hereinafter with reference to the accompanying drawings. Incidentally, the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc. of the respective parts are schematically illustrated in the drawings, compared to the actual modes. However, the schematic illustration is merely an example, and adds no restrictions to the interpretation of the invention. Besides, in the specification and drawings, the structural elements having functions, which are identical or similar to the functions of the structural elements described in connection with preceding drawings, are denoted by like reference numerals, and an overlapping detailed description is omitted unless otherwise necessary.

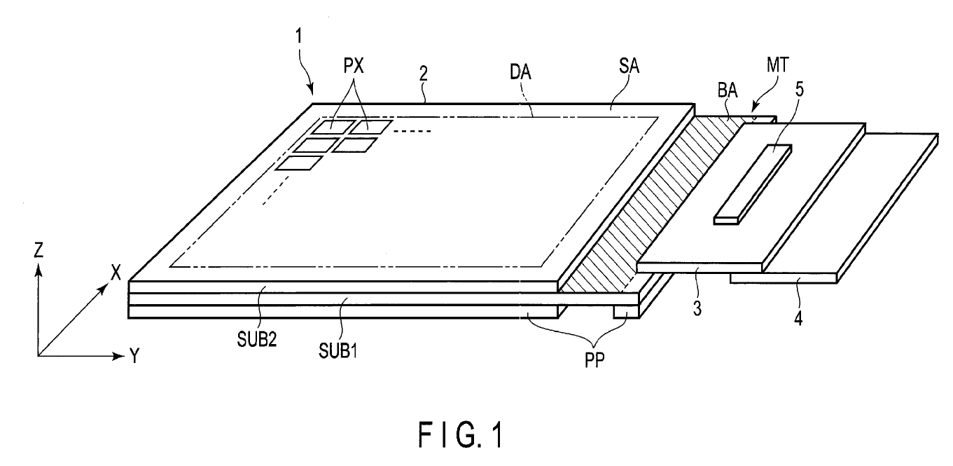

FIG. 1 is a perspective view showing schematically a display device 1 according to this embodiment. In this embodiment, an organic EL display device which employs an organic electroluminescence (EL) element will be discussed as an example of the display device 1, but it may be of some other type, for example, a liquid crystal display comprising a liquid crystal layer or an electronic-paper type display device comprising an electrophoresis element. FIG. 1 illustrates a three-dimensional space defined by a first direction X, a second direction Y orthogonal to the first direction X, and a third direction Z orthogonal to the first direction X and the second direction Y. The first direction X and the second direction Y cross each other perpendicularly, but they may cross at an angle other than 90 degrees. Moreover, for example, the first direction X is parallel to short sides of the display device 1, the second direction Y is parallel to long sides of the display device 1, and the third direction Z is equivalent to a thickness direction of the display device 1.

In this embodiment, the positive direction of the third direction Z is defined as up or above, and the negative direction of the third direction Z is defined as down or below. Further, such expressions as “the second member above the first member” and “the second member below the first member”, the second member may be in contact with the first member or may be separated from the first member. In the case of the latter, the third member may be interposed between the first member and the second member.

The display device 1 comprises a display panel 2, a first circuit substrate 3, a second circuit substrate 4 and the like. The display panel 2 comprises a first substrate SUB1 and a second substrate SUB2 disposed to oppose the first substrate SUB1.

The display panel 2 includes a display area DA, a peripheral area SA surrounding the display area DA and a mounting portion MT. The display area DA is an area where images are displayed, and comprises a plurality of pixels PX arrayed in, for example, a matrix. The pixels PX each include a light-emitting device, which will be described later and a switching element which drives the light-emitting device, etc.

The mounting portion MT is provided on one end side of the display panel 2 in the second direction Y. That is, the first substrate SUB1 includes a portion extending out from the region overlapping the second substrate SUB2. More specifically, three side edges of the first substrate SUB1 are aligned with respective three side edges of the second substrate SUB2 in the third direction Z. Each side edge of the first substrate SUB1, which is parallel to the first direction X and a respective side edge of the second substrate SUB2, which is parallel to the first direction X have a substantially same length. Each side edge of the first substrate SUB1, parallel to the second direction Y is longer than a respective side edge of the second substrate SUB2, parallel to the second direction Y. That is, an area of the first substrate SUB1, parallel to an X-Y plane is larger than an area of the second substrate SUB2, parallel to the X-Y plane. Here, the X-Y plane is a plane defined by the first direction X and the second direction Y. In this embodiment, the side edges of substrate SUB2, parallel to the second direction Y may be substantially equal in length to the respective side edges of the first substrate SUB1, parallel to the second direction Y. In this case, the area of the second substrate SUB2, parallel to the X-Y plane is substantially the same as the area of first substrate SUB1, parallel to the X-Y plane.

The first circuit substrate 3 and the second circuit substrate 4 are provided on one end side of the display panel 2 in the second direction Y.

The first circuit substrate 3 is provided between the display panel 2 and the second circuit substrate 4. The first circuit substrate 3 is a flexible printed circuit substrate, for example. In the example illustrated, the first circuit substrate 3 is mounted above the mounting portion MT. The display panel 2 and the first circuit substrate 3 are electrically connected to each other. The first circuit substrate 3 comprises a drive IC chip 5 which drives the display panel 2, etc. In the example illustrated, the driving IC chip 5 is mounted above the first circuit substrate 3, but may be below the circuit substrate 3. In the example illustrated, the length of side edges of the first circuit substrate 3, parallel to the first direction X is less than the length of the respective side edges of the first substrate SUB1 and second substrate SUB2, parallel to the first direction X, but they may be substantially equal respectively to each other.

The second circuit substrate 4 is a flexible printed circuit substrate, for example. The second circuit substrate 4 is connected to the first circuit substrate 3, for example, under the first circuit substrate 3.

Here, in this embodiment, the display device 1 includes a bending area BA, which is a region bent when accommodated in a housing such as of an electronic device. The bending area BA is hatched in the figure. The bending area BA is bent so as to place the first circuit substrate 3 and the second circuit substrate 4 below the display area DA.

A protection member PP is attached to below the display panel 2. The protection member PP is not placed at a position overlapping the bending area BA in the third direction Z.

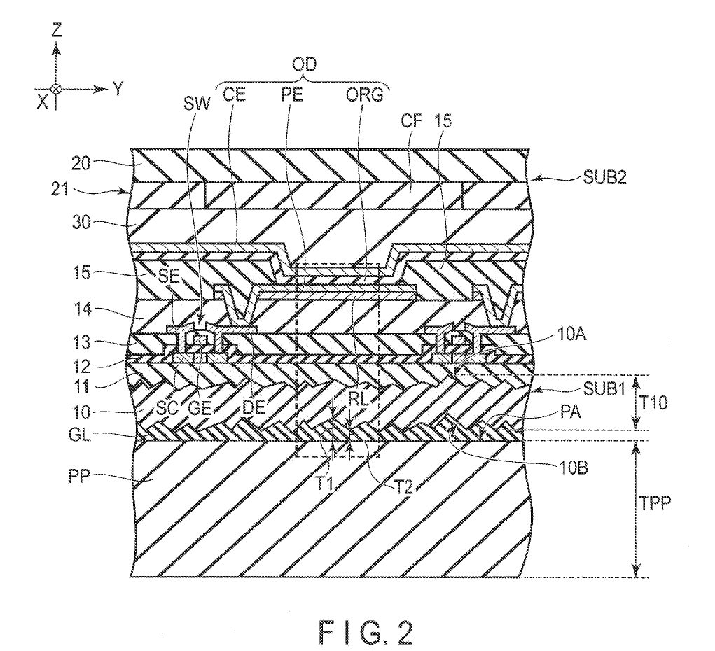

FIG. 2 is a cross section of the display area DA of the display device 1 according to this embodiment.

As shown in FIG. 2, the first substrate SUB1 comprises a first insulating substrate 10, switching elements SW and an organic EL device OD as a light-emitting device, etc.

The first insulating substrate 10 is formed of, for example, an organic insulating material such as polyimide. The first insulating substrate 10 comprises a first surface 10A and second surface 10B, which is a surface on an opposite side to the first surface 10A. The organic EL device OD is formed on a first surface 10A side. The protection member PP is formed on a second surface 10B side with an adhesive member GL. The protection member PP is a protection film which protects the first insulating substrate 10 and is formed of, for example, polyethylene terephthalate (PET). The protection member PP comprises a third surface PA attached onto the second surface 10B. For example, a thickness TPP of the protection member PP is greater than a thickness T10 of the first insulating substrate 10.

In this embodiment, at least one of the first surface 10A and the second surface 10B is a rough surface with projections and recesses. The rough surface will be described in detail later, but the grade of a rough surface can be defined by, for example, the surface coarseness. In the example shown in FIG. 2, both of the first surface 10A and the second surface 10B are rough surfaces. The surface coarseness of the second surface 10B is substantially equal to or more than that of the first surface 10A. Further, the surface coarseness of the second surface 10B is more than the surface coarseness of the third surface PA. Note that the surface coarseness described here is a value (for example, an arithmetically obtained average roughness Ra) defined (or measured) based on JIS B 0601 (1994).

The adhesive member GL is in contact with the third surface PA, which is more even than the second surface 10B and the second surface 10B. Thus, the adhesive member GL includes a region in the X-Y plane, whose thickness differs from one location to another. More specifically, a thickness T1 of the adhesive member GL in contact with the recesses of the second surface 10B is greater than a thickness T2 of the adhesive member GL in contact with the projections adjacent respectively to the projections.

On the first surface 10A of the first insulating substrate 10, a first insulating film 11 is formed as an overcoat layer. The first insulating film 11 is in contact with the first surface 10A. The first insulating film 11 may be omitted. Moreover, the first insulating film 11 may contain a barrier layer to suppress the entering of moisture or the like, from the first insulating substrate 10 towards the organic EL device OD.

The switching elements SW are formed on the first insulating film 11. The switching elements SW are each a thin film transistor (TFT), for example. The switching elements each comprise a semiconductor layer SC, a gate electrode GE, a source electrode SE and a drain electrode DE. The semiconductor layer SC is formed on the first insulating film 11 and is covered by a second insulating film 12. The gate electrode GE is formed on the second insulating film 12 and is covered by a third insulating film 13. The source electrode SE and the drain electrode DE are both formed on the third insulating film 13 and are in contact with semiconductor layer SC. The first to third insulating films 11 to 13 are each formed from an inorganic insulating material such as silicon oxide, silicon nitride or silicon oxynitride. In this embodiment, the first insulating film 11 is equivalent to an inorganic insulating layer. In the example illustrated, the switching element SW is of a top-gate type, but it may be of a bottom-gate type.

The switching element SW is covered by a fourth insulating film 14. The fourth insulating film 14 is formed from an organic insulating material.

The organic EL device OD is formed on the fourth insulating film 14. In the example illustrated, the organic EL device OD is of the so-called top-emission type, which emits light to an opposite side to the first insulating substrate 10, but may be of the so-called bottom-emission type, which emits light to a first insulating substrate 10 side. The organic EL device OD comprises a pixel electrode PE, a common electrode CE and an organic light-emitting layer ORG between the pixel electrode PE and the common electrode CE.

The organic EL device OD is partitioned into each pixel PX with a rib 15 formed from an organic insulating material. That is, in a region where the rib 15 is provided, the pixel electrode PE and the organic light-emitting layer ORG are not in contact with each other (that is, insulated from each other), and therefore the organic light-emitting layer ORG does not emit light.

The pixel electrode PE is provided on the fourth insulating film 14. The pixel electrode PE is in contact with the drain electrode DE of the switching element SW via a contact hole formed in the fourth insulating film 14, and is electrically connected to the switching element SW. As shown in FIG. 2, in the case of the top-emission type, the organic EL device OD should preferably include a reflective layer RL between the fourth insulating film 14 and the pixel electrode PE. The reflective layer RL is formed from, for example, a metal material with high-reflectivity, such as aluminum. The reflective layer RL may be even as illustrated, or may be an uneven surface to be light-scatterable.

The organic light-emitting layer ORG emits light at a luminance according to a voltage (or current) applied between the pixel electrode PE and the common electrode CE. The organic light-emitting layer ORG may include other layers in addition to the light-emitting layer, such as an electron-injection layer, a hole-injection layer, an electron-transport layer, and a hole-transport layer, to improve luminous efficiency.

The common electrode CE is formed on the organic light-emitting layer ORG. The common electrode CE and the pixel electrode PE are formed from, for example, a transparent conductive material such as indium tin oxide (ITO) or indium zinc oxide (IZO). Note that though omitted from the illustration, the organic EL device OD should preferably be sealed with a protection film to protect the organic EL device OD from moisture and the like.

The organic EL device OD is covered by a sealing layer 30. The sealing layer 30 is formed to seal the members disposed between the first insulating substrate 10 and the sealing layer 30. The sealing layer 30 inhibits entering of oxygen and moisture to the organic EL device OD, to suppress degradation of the organic EL device OD. The sealing layer 30 may be formed from a stacked layer body of an inorganic film and an organic film.

On the other hand, the second substrate SUB2 comprises a second insulating substrate 20, a color filter layer 21 and the like. The second insulating substrate 20 may be a glass substrate or a resin substrate, or an optical element containing an optical film, a polarizer, etc. The color filter layer 21 is provided on an inner side of the second insulating substrate 20 (that is, a side which opposes the first substrate SUB1). The color filter layer 21 comprises color filters CF. The color filters CF are formed from, for example, resin materials colored red, blue, green, white, etc.

The first substrate SUB1 and the second substrate SUB2 prepared as above are attached together with the sealing layer 30, for example. The color filters CF provided on the second substrate SUB2 are arranged so as to cover at least the light-emitting regions of the organic EL device OD formed on the first substrate SUB1.

In the example illustrated, the organic EL device OD is formed so as to comprise a common organic light-emitting layer ORG provided for a plurality of pixels PX, but the structure thereof is not limited to this. For example, an organic light-emitting layer which emits blue light, an organic light-emitting layer which emits green light, and an organic light-emitting layer which emits red light may be provided for every pixel. In such structure, the color filter layer 21 may be omitted.

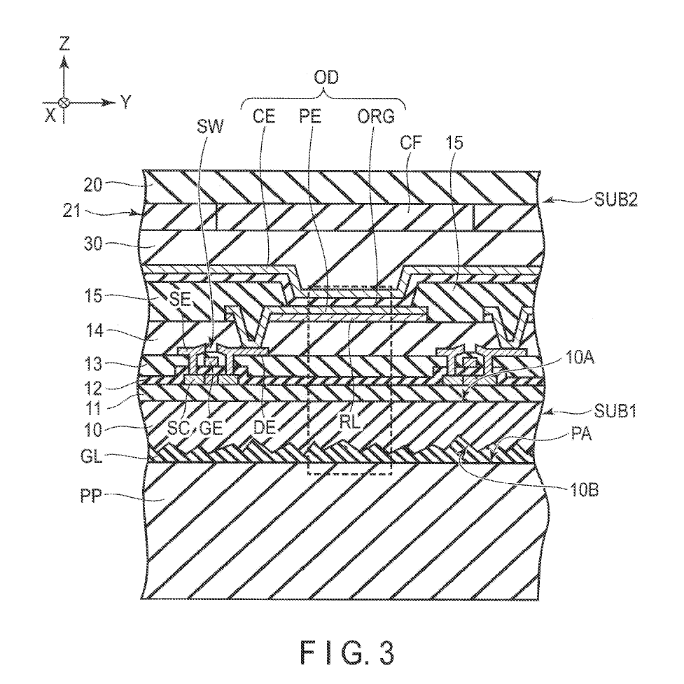

FIG. 3 is a cross section showing another example of the display area DA of the display device 1 according to this embodiment. As compared to the example shown in FIG. 2, the example shown in FIG. 3 is different in that the surface coarseness of the second surface 10B is more than that of the first surface 10A, and the other structure is the same as that of FIG. 2. In the example shown in FIG. 3, the first surface 10A is substantially an even surface, whereas the second surface 10B is a rough surface.

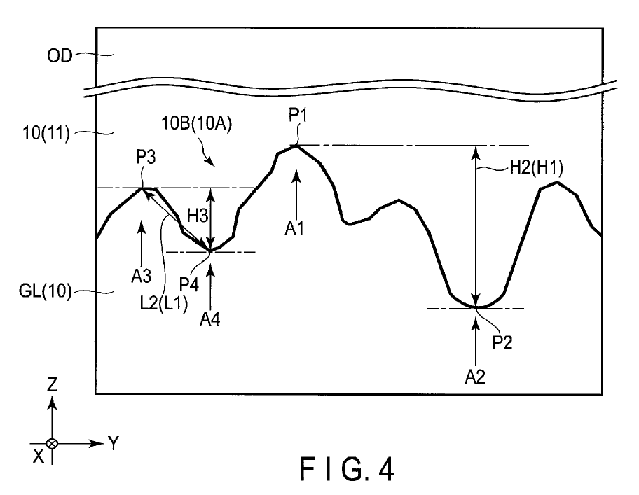

FIG. 4 is an enlarged cross section showing a portion encircled by the dotted line in FIG. 2 and FIG. 3. The following description focuses on the second surface 10B as an example, but it is also the case for the first surface 10A except that projections and recesses with respect to each other are reversed between the first surface 10A and the second surface 10B. That is, for example, when the cross section of the second surface 10B is shown as an example, a region A1 including a first position P1 is recessed, whereas a region A2 including a second position P2 projects. On the other hand, when the cross section of the first surface 10A is shown as an example, the region A2 including the second position P2 is recessed, whereas the region A1 including the first position P1 projects.

In FIG. 4, the third direction Z is equivalent to the thickness direction of the first insulating substrate 10.

The second surface 10B is formed such that a distance H2 between the first position P1 closest to the organic EL device OD in the thickness direction of the first insulating substrate 10 and the second position P2 farthermost from the organic EL device OD in the thickness direction becomes 0.01 μm or more but 10 μm or less, preferably, 0.1 μm or more but 10 μm or less. Moreover, in the second surface 10B, also, a distance between a recess and a projection adjacent to each other can be specified. For example, a region A3 is equivalent to a recess, and a region A4 is equivalent to a projection adjacent to the region A3. A distance L2 of a third position P3, which is a bottom of the region A3 and a fourth position P4, which is a top of the region A4 is set to 15 μm or less. Note that a distance H3 between the third position P3 and the fourth position P4 along the thickness direction, that is, the distance H3 along thickness direction between a recess and a projection adjacent to each other is 0.01 μm or more but 10 μm or less, preferably, 0.1 μm or more but 10 μm or less.

In the case where the thickness of the first insulating substrate 10 is greater than 20 μm, for example, the first surface 10A may become more even than the second surface 10B. In other words, a surface coarseness Ra1 of the first surface 10A may be less than a surface coarseness Ra2 of the second surface 10B. In such a case, a distance H1 in the thickness direction between a first position P1 and a second position P2 in the first surface 10A may be less than the distance H2 in the thickness direction of the first position P1 and the second position P2 in the second surface 10B. Or between an adjacent pair of a recess and a projection, a distance L1 between a third position P3 and a fourth position P4 in the first surface 10A may be less than the distance L2 between the third position P3 and the fourth position P4 in the second surface 10B.

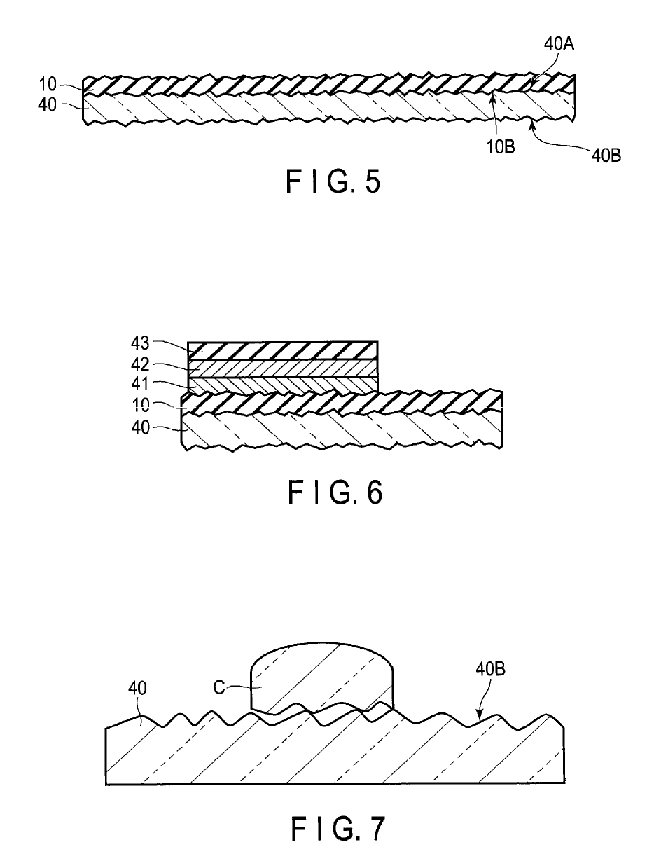

Next, a method of manufacturing the display device 1 will be described with reference to FIGS. 5 to 12.

First, as shown in FIG. 5, the first insulating substrate 10 formed from, for example, an organic insulating material such as polyimide is formed on a front surface 40A of a glass substrate 40. Here, the front surface 40A of the glass substrate 40 is formed to be rough. Details of the technique of forming the glass substrate 40 to have a rough surface will be omitted here, but, such a technique of corroding the surface chemically with fluoric acid, for example, is applicable. Thus, in the first insulating substrate 10, at least the second surface 10B, which is brought into contact with the front surface 40A of the glass substrate 40, is formed into a rough surface as in the front surface 40A of the glass substrate 40.

In the example illustrated, both of the front surface 40A and a rear surface 40B of the glass substrate 40 are formed into rough surfaces, but in order to form a rough-surfaced first insulating substrate 10, it suffices if at least the front surface 40A, on which the first insulating substrate 10 is formed, is formed to be rough. In order to prevent foreign matters from attaching to the glass substrate 40, which will be described later, it suffices if the rear surface 40B is formed to be rough. The above-provided description with reference to FIG. 4 is applicable also to the front surface 40A and the rear surface 40B of the glass substrate 40. That is, when at least one of the front surface 40A and the rear surface 40B of the glass substrate 40 is a rough surface, a distance between a first position P1 and a second position P2 along the thickness direction is set to 0.01 μm or more but 10 μm or less, preferably 0.1 μm or more but 10 μm or less, and a distance between a third position P3 and a fourth position P4 is set to 15 μm or less. In addition, a distance between the third position P3 and the fourth position P4 along the thickness direction, i.e., the distance along the thickness direction of the glass substrate 40 between a recess and a projection adjacent to each other is set to 0.01 μm or more but 10 μm or less, preferably 0.1 μm or more but 10 μm or less.

Next, as shown in FIG. 6, an array layer 41 containing the switching element SW is formed on the first insulating substrate 10. The array layer 41 is equivalent to the layers from the first insulating film 11 to the fourth insulating film 14 shown in FIGS. 2 and 3. Subsequently, a display function layer 42 containing the organic EL device OD is formed on the array layer 41. The display function layer 42 is equivalent to the layers from the reflective layer RL to the common electrode CE shown in FIGS. 2 and 3. Note that the surface of the organic EL device OD is sealed with a protection film if needed. Then, the glass substrate 40 is cut into halves. Here, the glass substrate 40 may be cut so as to contain a plurality of display devices 1 in cut pieces, or cut into such a size (of an individual cell piece) corresponding to one display device 1. Or, the glass substrate 40 need not be cut.

Next, an optical layer 43 containing the insulating substrate 20 is attached onto the display function layer 42. The optical layer 43 is equivalent to the second substrate SUB2 shown in FIGS. 2 and 3. The optical layer 43 may contain, for example, a polarizer. Then, the glass substrate 40 is washed if needed.

FIG. 7 is a cross section schematically showing the glass substrate before washing.

For example, when the glass substrate 40 is cut, glass chips (cullet) may be created while cutting. The rear surface 40B of the glass substrate 40 is formed rough to such an extent that it includes recesses and projections sufficiently smaller than the size of the cullet. Therefore, as shown in FIG. 7, a crevice is created between a cullet C and the rear surface 40B of the glass substrate 40. As a result, it is possible to suppress the cullet C from being entirely attached to the rear surface 40B of the glass substrate 40, and therefore the cullet C can be easily removed.

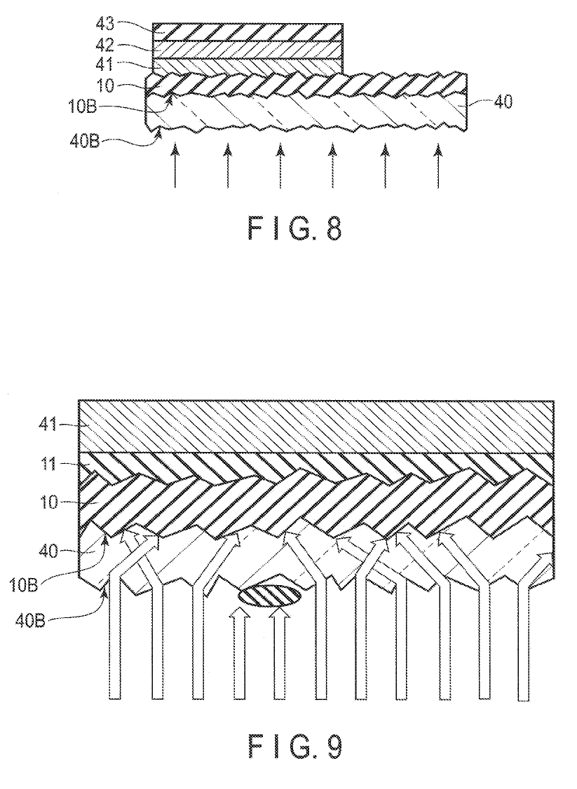

Next, as shown in FIG. 8, the glass substrate 40 is irradiated with a laser beam, and the glass substrate is peeled off from the first insulating substrate 10.

The laser beam irradiated onto the glass substrate 40 is of a wavelength of 355 nm. The laser beam is irradiated from under the glass substrate 40 (that is, the rear surface 40B side of the glass substrate 40), and transmitted through the glass substrate 40, and then reaches the second surface 10B of the first insulating substrate 10. The first insulating substrate 10 absorbs the laser beam in the vicinity of the interface between the glass substrate 40 and the first insulating substrate 10, to cause ablation, by which the first insulating substrate 10 is partially decomposed. Thus, a space is created between the glass substrate 40 and the first insulating substrate 10, peeling the glass substrate 40 off from the first insulating substrate 10.

FIG. 9 is a cross section showing schematically a state where the laser beam is being irradiated.

In the example illustrated, a foreign matter is attached to the rear surface 40B of the glass substrate 40. Here, even if a foreign matter is not removed in washing and still attached to the rear surface 40B of the glass substrate 40 as shown in FIG. 9, it is possible to apply the laser beam to reach the second surface 10B of the first insulating substrate 10. That is, the rear surface 40B of the glass substrate 40 is formed rough and therefore the laser beam is scattered by the rear surface 40B. The scattered laser beam travels around and enters the region covered by the foreign matter to be able to reach the second surface 10B of the first insulating substrate 10. In this manner, it becomes possible to suppress the peeling error of the glass substrate 40. Thus, the glass substrate 40 can be peeled off from the first insulating substrate 10.

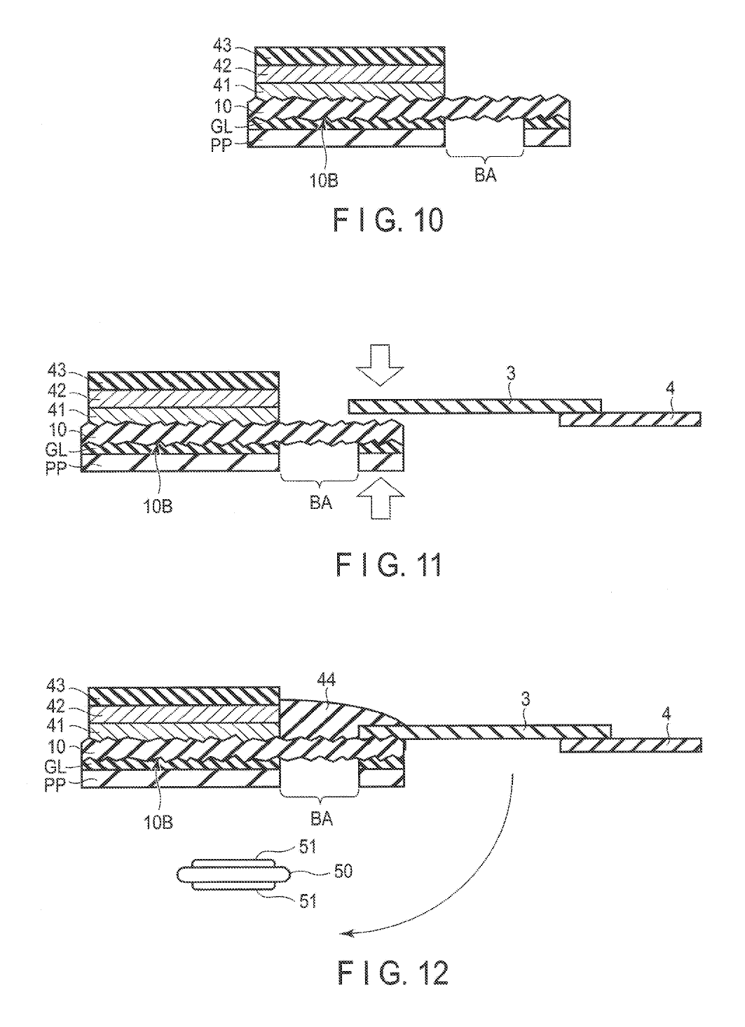

Next, as shown in FIG. 10, the protection member PP is attached onto the second surface 10B of the first insulating substrate 10 via the adhesive member GL. More specifically, the protection member PP is aligned while disposing an adhesive sheet or the like as the adhesive member GI between the first insulating substrate 10 and the protection member PP. Then, heat treatment is carried out to attach the protection member PP under the first insulating substrate 10. Thus, after alignment, the protection member PP is heat-treated, and therefore it is possible to suppress position shifting. Further, the adhesive member GL and the protection member PP are attached onto the region except the bending area BA.

Next, as shown in FIG. 11, the first circuit substrate 3 is bonded by pressing to the first insulating substrate 10. That is, an anisotropic conducting film (not shown) is placed between the first insulating substrate 10 and the first circuit substrate 3 and pressure is applied to the direction indicated by arrows shown in FIG. 11 from below the first insulating substrate 10 and above the first circuit substrate 3, followed by heating. Thus, the anisotropic conducting film fuses to electrically and physically connect the first insulating substrate 10 and the first circuit substrate 3 to each other.

Next, as shown in FIG. 12, the bending area BA of the display panel 2 is bent. First, in order to prevent the entering of moisture and the like from an end of the first circuit substrate 3, an end of the array layer 41 and an end of the display function layer 42, a resin layer 44 is provided on the bending area BA. The resin layer 44 is, for example, an organic insulating material, and formed as it is cured by UV irradiation.

Next, a support member 50 is aligned and attached to the protection member PP via an adhesive member 51. Then, the bending area BA of the display panel 2 is bent so as to dispose the first circuit substrate 3 and the second circuit substrate 4 below the display area DA. More specifically, the first circuit substrate 3 and the second circuit substrate 4 is pivoted around the support member 50 so as to be located thereunder and attached to the support member 50 via the adhesive member 51. In this embodiment, the thickness of the display panel PNL in the bending area BA is, for example, about 130 μm. Note that the support member 50 need not be provided.

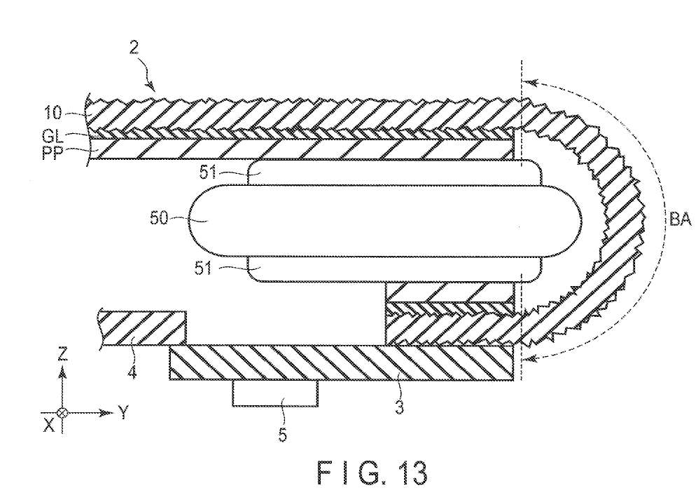

FIG. 13 is a cross section showing the bending area BA of the display panel 2 shown in FIG. 12 after bent. FIG. 13 illustrates only the main portion and the array layer 41 and the like are omitted.

The bending area BA is bent so that the display panel 2 opposes the first circuit substrate 3 and the second circuit substrate 4. In this embodiment, the radius of curvature can be set to 1.0 mm or less and the radius of curvature of the bending area BA is, for example, about 0.3 mm. The support member 50 is located between the protection member PP and the first circuit substrate 3. With the support member 50 provided, the display panel 2 and the first circuit substrate 3 can be protected from being easily damaged even when a shock is applied from outside. Further, with the support member 50, the adhesiveness between the protection member PP and the first circuit substrate 3 can be improved.

Note that the above-described process is an example and the processing steps are not limited to the above-indicated order.

According to this embodiment, the display device 1 comprises the first insulating substrate 10 including the first surface 10A and the second surface 10B, at least one of which is a rough surface. Since the first insulating substrate 10 is formed to have a rough surface, it becomes possible to ease concentration of stress, and therefore the first insulating substrate 10 can be easily bent. Further, when the second surface 10B to be attached to the protection member PP is formed rough as well, the contact area between the second surface 10B and the adhesive member GL is increased, making it possible to improve the adherence of the protection member PP.

Moreover, in the glass substrate 40, the front surface 40A on which the first insulating substrate 10 is formed and the rear surface 40B on the opposite side to the front surface 40A are formed rough, it is possible to suppress foreign matters and the like from attaching to the rear surface 40B of the glass substrate 40. Further, even if a foreign matter or the like attaches to the rear surface 40B of the glass substrate 40, it can be easily removed.

Furthermore, the laser beam to peel the glass substrate 40 off from the first insulating substrate 10 is scattered on the rear surface 40B of the glass substrate 40, and therefore even if a foreign matter is attached to the rear surface 40B of the glass substrate 40, it is possible to apply the laser beam to reach the second surface 10B of the first insulating substrate 10. Thus, the peeling-off error of the glass substrate can be suppressed.

As described above, with use of the glass substrate 40 comprising a rough surface in the manufacture of the display device 1, the yield of the product can be easily improved.

In addition, when the display device 1 is a liquid crystal display, the liquid crystal display may be any of a transmissive type which displays images by selectively transmitting light from a rear side thereof, a reflective type which displays images by selectively reflecting light from a front side thereof and a trans-reflective type comprising a transmissive display function and a reflective display function. When the display device 1 is a liquid crystal display, the above-described display function layer 42 is equivalent to the layers containing a pixel electrode, a liquid crystal layer and a common electrode.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
an insulating substrate on which a display function layer is provided; and
a protection member attached onto the insulating substrate,
the insulating substrate further comprising a first surface on which the display function layer is formed and a second surface on an opposite side to the first surface, on which the protection member is attached, and
at least one of the first surface and the second surface comprising a projection and a recess.

2. The display device of claim 1, wherein
a surface coarseness of the second surface is greater than that of the first surface.

3. The display device of claim 1, wherein
the protection member comprises a third surface opposing the second surface of the insulating substrate, and
the surface coarseness of the second surface is greater than that of the third surface.

4. The display device of claim 1, further comprising:
an inorganic insulating layer located between the display function layer and the first surface and in contact with the first surface,
an adhesive member in contact with the protection member and the second surface.

5. The display device of claim 4, wherein
the second surface comprises the projection and the recess,
the projection and the recess are adjacent each other, and
a thickness of a portion of the adhesive member, which is in contact with the recess is greater than a thickness of a portion of the adhesive member, which is in contact with the projection.

6. The display device of claim 1, wherein
the insulating substrate and the protection member are each formed of an organic insulating material, and
a thickness of the protection member is greater than that of the insulating substrate.

7. The display device of claim 1, wherein
the second surface comprises the projection and the recess,
the projection and the recess are adjacent each other, and
a distance between the recess and the projection along a thickness direction of the insulating substrate is 0.01 μm or more but 10 μm or less.

8. The display device of claim 1, wherein
the second surface comprises a first position closest to the display function layer along a thickness direction of the insulating substrate and a second position apart from the first position and most distant from the display function layer along the thickness direction of the insulating substrate.

9. The display device of claim 8, wherein
a distance between the first position and the second position along the thickness direction is 0.01 μm or more but 10 μm or less.

10. The display device of claim 1, wherein
the second surface comprises a third position and a fourth position adjacent to the third position, and
a distance between of the third position and the fourth position 15 μm or less.
